(19) United States
(12) Patent Application Publication
(10) Pub. No.: US 2026/0223613 A1
(43) Pub. Date: Jul. 30, 2026

(54) METHODS OF MANUFACTURING SUPERCONDUCTING VIA THROUGH SEMICONDUCTOR WAFER

(71) Applicant: Oxford Instruments Nanotechnology Tools Limited, High Wycombe (GB)

(72) Inventors: Zhong Ren, High Wycombe (GB); Yi Shu, High Wycombe (GB)

(73) Assignee: Oxford Instruments Nanotechnology Tools Limited, High Wycombe (GB)

(21) Appl. No.: 19/146,030

(22) PCT Filed: Jan. 11, 2024
(86) PCT No.: PCT/GB2024/050060

§ 371 Date: Jul. 7, 2025

(30) Foreign Application Priority Data
Jan. 13, 2023 (GB) 2300559.8

(51) Int. Cl. H10P 50/24; H10P 50/00; H10W 20/00

(52) U.S. Cl. CPC H10P 50/242; H10P 50/691; H10W 20/0261

(57) ABSTRACT

A method of manufacturing a superconducting via through a semiconductor wafer having opposed first and second surfaces. The method comprises: (A) forming, at least partly, a via extending through the semiconductor wafer from the first surface to the second surface by etching into the first surface of the semiconductor wafer using a first plasma etching process; and then: (B) using a second plasma etching process different from the first plasma etching process, etching the wall of the via so as to reduce its surface roughness; (C) after step (B), depositing a superconductor material on at least a portion of the wall of the via; and (D) if the via was not formed completely in step (A), completing the formation of the via such that the via extends from the first surface to the second surface of the semiconductor wafer; whereby the deposited superconductor material forms an electrically conductive pathway electrically connecting the first and second surfaces of the semiconductor wafer.

### CROSS-REFERENCE TO RELATED APPLICATIONS

The present application is the U.S. national stage application of international application PCT/GB2024/050060 filed Jan. 11, 2024, which international application was published on Jul. 18, 2024, as International Publication WO 2024/150003 A1. The international application claims priority to British Patent Application No. 2300559.8, filed Jan. 13, 2023. The international and British applications are hereby incorporated by reference herein.

### FIELD OF THE INVENTION

This invention relates to methods of manufacturing an electrically conductive via through a semiconductor (e.g. silicon) wafer. Vias manufactured by methods in accordance with the invention find particular application in the manufacture of electronic devices for quantum applications, such as quantum computing and superconducting nanowire single photon detectors, since they can be employed to realise 3D integration of quantum circuits.

### BACKGROUND TO THE INVENTION

In many quantum processors, the quantum computing components (e.g. the devices that implement and manipulate the quantum mechanical systems on which computations are performed) are typically arranged on one side of a semiconductor wafer (e.g. a silicon wafer) and are in communication with other devices arranged on the opposite side of the wafer, or to other areas on the same side of the wafer, or to devices on a separate wafer. Such communication can be achieved by forming one or more electrical connections through the wafer by the provision of “through-substrate vias” (TSVs) (often referred to as “through-silicon vias”, where the substrate is silicon) extending through the wafer and forming a conductive pathway between its two sides. This is important for increasing the scalability of electronics for quantum computing and other quantum applications. Because quantum processors of the kind just described operate at cryogenic temperatures (e.g. below 10 Kelvin (K)), the vias must be superconducting to ensure that they do not experience resistive heating and thereby raise the temperature of the quantum computing components. Moreover, the transition temperature of the via (above which it ceases to be superconductive and acquires a non-zero resistance) must be sufficiently high that the via is superconductive across the temperature range at which the quantum processor operates. A transition temperature of at least 10 K is desirable for many quantum applications, in particular quantum computing and other applications that employ 3D integration of quantum circuits.

Previous attempts to manufacture superconducting TSVs have encountered difficulties in reliably producing vias that exhibit superconductivity and have a suitably high transition temperature. For example, attempts have been made to produce superconducting vias by lining the wall of a via through the wafer with a deposited superconductor material such as titanium nitride, but these approaches have generally either failed altogether to produce vias that exhibit superconductivity reliably or, where they have succeeded in producing superconducting vias, produced vias with transition temperatures that are below the range at which most quantum processors preferably operate. For example, many attempts have produced vias with transition temperatures of about 2 K, whereas, as mentioned above, a transition temperature of at least 10 K is desirable for many quantum applications.

An aim of the present invention is to provide a way of reliably manufacturing superconducting vias through a semiconductor wafer that exhibit a high transition temperature.

### SUMMARY OF THE INVENTION

A first aspect of the invention provides a method of manufacturing a superconducting via through a semiconductor wafer having opposed first and second surfaces, the method comprising:
(A) forming, at least partly, a via extending through the semiconductor wafer from the first surface to the second surface by etching into the first surface of the semiconductor wafer using a first plasma etching process; and then:
(B) using a second plasma etching process different from the first plasma etching process, etching the wall of the via so as to reduce its surface roughness;
(C) after step (B), depositing a superconductor material on at least a portion of the wall of the via; and
(D) if the via was not formed completely in step (A), completing the formation of the via such that the via extends from the first surface to the second surface of the semiconductor wafer;
whereby the deposited superconductor material forms an electrically conductive pathway electrically connecting the first and second surfaces of the semiconductor wafer.

The inventors have realised that the limited success of previous attempts to manufacture superconducting through-substrate vias is in part a consequence of irregularity in the surface on which the superconductor material is deposited. Most techniques by which a via through the wafer can be formed (for example mechanical drilling or plasma etching) impart significant surface roughness and/or other irregularity to the wall of the via, which severely limits the ability of the deposited superconductor material to form a uniform, ordered film on the wall. In the method above, two plasma etching processes are employed to produce a smooth wall suitable for subsequent deposition of the superconductor material: a first plasma etching process is used to etch the via through the wafer and then a second plasma etching process is used to smooth the wall of the etched via (this step can be referred to as a “plasma polish”), thereby promoting the formation of a uniform, ordered film of superconductor material on the wall. The first plasma etching process will typically be a process suitable for deep etching of semiconductor materials—for example (as will be the case in some preferred embodiments, described below) a Bosch process. However, such processes typically leave significant roughness and/or other irregularity (such as scalloping, in the case of the Bosch process), so a second plasma etching process is used to smooth the wall of the etched via. Various plasma etching techniques are suitable for smoothing the side walls of etched features, one example of which is reactive ion etching (which is employed in some preferred embodiments, which will be discussed below). It will be appreciated that a plurality of vias through a single semiconductor wafer may be formed using the method above, typically by performing the method at several locations on the wafer simultaneously.

By “semiconductor wafer” we mean an integral layer of semiconductor material, on which other components (e.g. epitaxial layers or other deposited material) may be provided (but any additional such layers do not form part of the wafer itself). For example, in a slice of crystalline silicon with a layer of silicon dioxide on one of its surfaces, the layer of crystalline silicon constitutes the “semiconductor wafer”.

A “superconductor material” is a material that exhibits superconductivity (i.e. zero resistance) below a critical temperature, the exact value of which depends on the superconductor material and the structure of the particular sample in question. Niobium nitride (NbN) is an example of such a material, and samples of this material can exhibit critical temperatures of up to about 17 K.

The reduction in roughness of the via wall defined in step (B) can be defined as a reduction in its root mean square (RMS) roughness, which is the root mean square average of deviations in the profile height from a mean line.

In general, the via may take any lateral shape (e.g. round, circular, square, slot), and any lateral width, though certain preferred dimensions and aspect ratios of the lateral dimensions to depth will be discussed below. Furthermore, the walls of the via may have a range of profiles: while in preferred embodiments the walls of the via are substantially parallel to one another and are substantially vertical (i.e. perpendicular to the plane of the wafer), other shapes are possible and can result from certain etching processes—for example, some etching processes may result in the via having a tapered shape (such that the via is narrower near one surface of the wafer and wider near the other surface) or an ‘hourglass’ shape (such that it is widest near the two surfaces of the wafer and is narrower mid-way between the two surfaces).

While the method above is defined in terms of a sequence of steps ((A), (B), (C), etc.), it will be appreciated that the steps do not have to be performed in the exact order in which they appear above. As indicated above by the expression “and then” after step (A), step (A) will always be before steps (B), (C), and (D) (since these steps are performed on the via formed in step (A)). Furthermore, step (B) will always be performed before step (C) (because the superconductor material deposited in step (C) is deposited onto the smoothed wall formed in step (B)). However, step (D), may be performed at any time after step (A)—i.e. before step (B), after step (B) and before step (C), or after step (C).

It will also be appreciated that the completion of the via in step (D) is only performed in instances where the via was not completely formed in step (A), as signified by the term “if” in step (D). In some embodiments, the via is completely formed in step (A), in which case there is no need to perform a separate step of completing the via in step (D).

In some preferred embodiments, the method further comprises: before step (A), providing the semiconductor wafer, the semiconductor wafer having a deposited layer (which may be an epitaxial layer but could be some other kind of deposited layer, for example a layer of an amorphous compound) on the second surface thereof, and wherein the deposited layer is present on the second surface of the semiconductor wafer during step (A), preferably also in step (B); and after step (A), if the deposited layer is not a superconducting deposited layer, removing the deposited layer from the second surface of the semiconductor wafer. The deposited layer here is on the second surface of the semiconductor wafer—i.e. the surface opposite the first surface, into which the via is etched in step (A). The presence of this deposited layer during step (A) can be beneficial for two main reasons: firstly, a cooling gas such as helium can be applied to the underside of this layer during the etching in step (A) to control the temperature of the wafer (thereby enabling improved control over the etching) and, secondly, it helps to prevent the material of the wafer rupturing when the via breaks through the second surface. The deposited layer may remain in place for step (B), in which case it may again be used for cooling the wafer by application of a cooling gas. The deposited layer will however ultimately be removed (at any time after step (A), or, if it is present in step (B), any time after step (B)).

In light of the above, in embodiments in which the deposited layer just described is present, the method preferably further comprises comprising applying a cooling gas, preferably helium, to the deposited layer during the etching in step (A), preferably also in step (B).

The deposited layer may advantageously be formed of silicon dioxide (SiO₂) (which may be deposited on the second surface of the wafer). This material is suitable for cooling the wafer by application of a cooling gas and can easily be removed, e.g. by reactive ion etching. It also has a high selectivity to Si etching—in other words, a process used to etch a via through a wafer made of Si will etch the SiO₂ layer much more slowly, which helps to ensure that the etching stops at the SiO₂ layer. Other materials with high selectivity to Si etching could also be used for forming this deposited layer.

As noted above, the via may be formed completely in step (A), in which case the optional completion of the via in step (D) is not performed. However, in some preferred embodiments, the via is formed partly in step (A), wherein completing the formation of the via in step (D) comprises removing material from the second surface of the semiconductor wafer. The formation of the via is thus completed once material has been removed from the second surface of the wafer, in step (D), such that the via opens onto the second surface (from which the material has been removed). For example, in step (A), the via may be etched such that it extends only part-way through the wafer (and therefore opens onto the first surface, but not onto the second surface, immediately after step (A)). Preferably the removal of material in step (D) is substantially uniform across the second surface of the semiconductor wafer, thereby thinning the wafer. In these embodiments, the formation of the via is completed in step (D) when the wafer has been thinned to the point at which the second surface meets the base of the etched via.

Where material is removed from the second surface in step (D), preferably the removal of material in step (D) is performed by plasma etching. For example, where the wafer is thinned in the manner just described, the etch could be an all-over etch (or ‘blanket etch’). Alternatively, material could be removed by chemical mechanical polishing (CMP) or wet etching.

The method may further comprise, after partly forming the via in step (A) and before completing the formation of the via in step (D), bonding a support substrate onto the first surface of the semiconductor wafer. Most preferably, the support substrate is bonded to the wafer after step (C). The support substrate could be another semiconductor wafer, for example. Bonding a support substrate to the wafer in this manner can be advantageous as it allows the second side of the wafer to be processed (e.g. by etching) while protecting the first surface (and the deposited superconductor material, if present). For example, advantageously, step (D) may be performed while the semiconductor wafer is bonded to the support substrate; in which case the method preferably further comprises separating the support substrate from the semiconductor wafer after step (D). It will be appreciated that the support substrate is not necessarily in direct contact with the second surface of the wafer when bonded to it—for example, there could be other structures and/or layers on the second surface (e.g. additional superconductor material on the second surface surrounding the opening of the via onto that surface), which will be between the support substrate and the semiconductor wafer when the two are bonded together.

In preferred embodiments, the superconductor material is deposited in step (C) by an atomic layer deposition (ALD) process, preferably plasma-enhanced atomic layer deposition. Atomic layer deposition is a cyclic process that enables the superconductor material to be deposited on the wall of the via one layer of atoms at a time, which allows a very uniform film of superconductor to be deposited in a controlled manner. The substrate is alternately exposed to two or more precursor gases, which each react in a self-limiting manner with the layer of material deposited in the previous step. The deposited material is thus deposited one layer at a time. Plasma-enhanced atomic layer deposition, in which a plasma is provided to influence the reactions undergone by the chemical precursors in each cycle of the process. is particularly suitable. Alternative processes such as chemical vapor deposition could also be used, however. A significant advantage of ALD processes (including PEALD) is that, thanks to the self-limiting nature of the deposition in each cycle, a uniform level of deposition can be achieved even across surfaces that experience variable degrees of exposure to the precursor gases. This makes ALD processes particularly suitable for depositing material on the (typically vertical) walls of the etched vias, even where the vias have high aspect ratios (i.e. where the depth of the via is large in relation to its lateral dimensions).

Preferably the method comprises depositing the superconductor material on the first surface and/or the second surface of the wafer such that the electrically conductive pathway extends from the via onto the first surface and/or the second surface. Extending the conductive pathway onto the first and/or second surface of the wafer in this manner can improve the ease of electrically connecting components on the respective surface to the via. It should be appreciated that the superconductor material deposited on the first surface and/or second surface is not necessarily deposited in the same deposition step as that which is deposited on the wall of the via—for example, superconductor material could be already present on the first and/or second surface prior to etching the via in step (A). Even if the superconductor material is not deposited on the first and/or second surfaces during the method, in some embodiments the wafer may be provided, before step (A), carrying superconductor material on the first surface and/or second surface arranged such that the electrically conductive pathway formed by the superconductor material deposited in step (C) extends from the via onto the first surface and/or the second surface.

Preferably, the etching in step (A) is performed through a patterned mask arranged on the first surface of the wafer and defining the lateral shape of the via; the method preferably further comprising, after step (A), removing the patterned mask. For example, the mask could be a photoresist mask or (particularly if cryo etching is used to etch the via in step (A)) a hard mask.

As mentioned previously, this invention aims to provide superconducting vias that exhibit superconductivity in the temperature ranges at which quantum devices such as quantum processors operate. Therefore, preferably, the resulting superconducting via has a superconducting transition temperature greater than 2 K (e.g. in the range of 2 K to 14 K), preferably greater than 10 K. Transition temperatures greater than 10 K have been achieved by methods in accordance with embodiments of the invention-though it will be appreciated that the benefits of the invention (for example higher critical temperature than previous methods) still arise when the critical temperature is not above 10 K.

Preferably the semiconductor wafer is formed of silicon. The silicon may be doped (p-type or n-type) or undoped (i.e. ‘intrinsic’) silicon. The method is however suitable for forming vias through wafers formed of other semiconductor materials.

In preferred implementations, the superconductor material is a metallic nitride, preferably niobium nitride (NbN). By “metallic nitride” we mean compounds of one or more metallic elements and nitrogen. Metallic nitrides, and NbN in particular, are capable of forming films with relatively high critical temperatures (e.g. above 10 K) and are therefore particularly suitable for forming superconducting vias for quantum computing applications. Other examples of metallic nitrides include titanium nitride, tantalum nitride and titanium niobium nitride. The deposited material may also be a mixture of several metallic nitrides and/or other superconductor materials. It will be appreciated that impurities such as carbon (C) could be present in the deposited metallic nitride or other superconductor material without preventing the deposited material from exhibiting superconductivity—for example, materials with formulae such as TaNₓC_{y} NbNₓC_{y} exhibit superconductivity.

Preferably the semiconductor wafer has a thickness in the range of 100 μm to 8000 μm. Many commercial products employ wafers having thicknesses in this range. For the avoidance of doubt, the term “thickness” here refers to the thickness of the wafer along the direction along which the first and second surfaces are separated. This refers to the thickness of the wafer once the via has been completed, so in embodiments where the wafer is thinned or otherwise has material removed after partly forming the via in step (A), the thickness range above refers to the thickness of the wafer after step (D). Accordingly, the via formed by the method above, which extends from the first surface of the wafer to its second surface, will have a depth in this range corresponding to the thickness of the wafer.

The etched via preferably has a smallest lateral dimension in the range of 0.2 μm to 5000 μm, preferably 60-80 μm. Methods in accordance with embodiments of the invention have been found to be particularly suitable for etching vias with dimensions in this range.

Preferably, the ratio of the thickness of the semiconductor wafer to the smallest lateral dimension of the etched via is in the range of 1:1 to 70:1, preferably 3:1 to 20:1, more preferably in the range of 4:1 to 10:1. By “smallest lateral dimension” we mean the smallest dimension that the via has in any lateral direction (i.e. any direction parallel to the plane of the wafer). For example, in the case of a via with a circular cross-section, this smallest dimension is the diameter. In the case of a rectangular cross-section, this smallest dimension is the length of the shorter side of the rectangle. The thickness of the wafer corresponds to the depth of the manufactured via, and if the depth of the via is too great relative to its lateral dimensions, it can become difficult to achieve uniform smoothing of the via's wall and deposition of superconductor material across the wall. The aspect ratios defined above have been found to enable suitably uniform smoothing and deposition and formation of high-quality crystal structure in the deposited material. Particularly where the thickness of the semiconductor wafer is large in relation to the lateral dimensions of the via, atomic layer deposition is preferred for depositing the superconductor material because this process is particularly effective at forming layers of a uniform thickness and quality over large distances and the amount of material deposited is (thanks to the self-limiting nature of the deposition) relatively unaffected by differences in the exposure of different parts of the via wall to plasma.

In some preferred embodiments, the first plasma etching process is a Bosch process or a cryo etching process. The Bosch process is particularly preferred since it allows rapid etching of deep vias with highly vertical sidewalls. Cryo etching processes are particularly effective for etching vias in comparatively thin wafers, e.g. those with a thickness of 300 μm or less. By “cryo etching” we mean plasma etching in which the substrate (e.g. semiconductor wafer) being etched is cooled to cryogenic temperatures during the etching.

Preferably the second plasma etching process is a reactive ion etching process. Reactive ion etching processes are particularly suitable for smoothing vertical features such as the walls of the via etched in step (A). Alternative processes suitable for this step include ion beam etching or ion beam milling.

Advantageously, the second plasma etching process may comprise etching the wall of the semiconductor wafer using a plasma generated from a gas mixture that comprises: at least one fluorine-bearing gas, more preferably at least one of CF₄, SF₆ and NF₃; and/or at least one of Ar, O₂ and H₂. By “fluorine-bearing gas” we mean a compound that releases fluorine radicals when present in a plasma, and CF₄, SF₆ and NF₃ are examples of compounds that exhibit this property. CF₄ is particularly preferred for this purpose, particularly where the second plasma etching process is a reactive ion etching process.

Preferably the second plasma etching process is performed at a pressure in the range of 1 mTorr to 500 mTorr, preferably about 10 mTorr. These values have been found to achieve good smoothing of the wall of the via.

Preferably, in step (B), the semiconductor wafer is arranged on a substrate table while the second plasma etching process is being performed. A bias voltage can be applied to such a table to increase the energy of ions colliding with the wafer, thereby affording improved control over the etching. Hence, preferably, an RF bias is applied to the substrate table during the second plasma etching process, wherein preferably: the RF bias has a value (in other words, generates a DC offset) in the range of 5 V to 1500 V, preferably about 400 V; and/or the power of the applied RF bias is in the range of 5 W to 1500 W, preferably about 100 W. These values of bias voltage and bias voltage power (particularly when applied in combination) have been found to achieve good results in reasonable time.

Preferably in the second plasma etching process, the plasma used to etch the wall of the semiconductor wafer is generated using an inductively-coupled plasma source (ICP, also sometimes referred to as a transformer couple plasma source, TCP) or an electron cyclotron resonance (ECR) plasma source, preferably at a power in the range of 100 W to 5000 W. The plasma could alternatively be generated using a capacitively-coupled plasma source, however.

A second aspect of the invention provides a method of manufacturing a superconducting via through a semiconductor wafer having opposed first and second surfaces, the method comprising:
(A) forming, at least partly, a via extending through the semiconductor wafer from the first surface to the second surface by etching into the first surface of the semiconductor wafer using a plasma etching process such that the wall of the etched via has a surface roughness of less than 30 nanometres (nm); and then:
(C) depositing a superconductor material on at least a portion of the wall of the via; and
(D) if the via was not formed completely in step (A), completing the formation of the via such that the via extends from the first surface to the second surface of the semiconductor wafer;
whereby the deposited superconductor material forms an electrically conductive pathway electrically connecting the first and second surfaces of the semiconductor wafer.

This method is similar to that defined above in relation to the first aspect. However, the wall of the via is not necessarily smoothed using a second plasma etching process distinct from that which was initially used to form the via (as in step (B) of the method of the first aspect)—but the via must be etched in step (A) such that its surface roughness (by which we mean the RMS roughness) is less than 30 nm. This aspect of the invention recognises that some plasma etching processes are capable of forming a via with a suitably smooth wall for deposition of high-quality superconductor material without requiring a separate smoothing step using a different plasma etching process. For example, the plasma etching process may be a cryo etching process, since cryo etching has been found to be capable of producing a suitably smooth wall for deposition of the superconductor material without an additional smoothing step. Cryo etching has also been found to produce highly vertical walls. It is believed that the smoothness and verticality of the walls of vias etched using cryo etching techniques is due to a passivating effect provided by the deposition of by-products of the etching on the walls of the etched via. These by-products are typically less volatile at lower (e.g. cryogenic) temperatures and therefore adhere better to the walls under these conditions. The via could also be etched using a Bosch process, though typically the cycles of the Bosch process will need to be controlled, by limiting the amount of material removed in each cycle of the process, so as to limit the size of the scallops formed in the via wall (such that the roughness introduced by the scallops is less than 30 nm). Scallops with heights of less than 25 nm can be produced in this way. Implementations of the second aspect of the invention employing the Bosch process are particularly suitable for forming vias in wafers with a thickness of less than 50 μm, since limiting the size of the scallops increases the number of cycles (and consequently the amount of time) required to etch through a given depth of the substrate.

The benefits of the method provided by the second aspect are the same as those achieved by the method of the first aspect—i.e. that it enables production of superconducting vias with high critical temperatures suitable for quantum applications. The method may however further comprise the step of: (B) before step (C), using a second plasma etching process different from the plasma etching process used to form the via in step (A) (which can in this case be referred to as a first plasma etching process), etching the wall of the via so as to reduce its surface roughness.

All of the preferred and other optional features of the method of the first aspect described above may also be implemented in embodiments of the second aspect, giving rise to the same advantages outlined above.

### BRIEF DESCRIPTION OF THE DRAWINGS

Examples of methods for manufacturing superconducting vias in semiconductor wafers in accordance with embodiments of the invention will now be described with reference to the drawings, in which:

FIG. 1 is a flowchart showing steps in a method according to embodiments of the invention;

FIGS. 2(a) to 2(d) illustrate the manufacture of an exemplary superconducting via at selected stages of a method according to a first embodiment;

FIGS. 3(a) to 3(e) illustrate the manufacture of an exemplary superconducting via at selected stages of a method according to a second embodiment;

FIGS. 4(a) to 4(f) illustrate the manufacture of an exemplary superconducting via at selected stages of a method according to a third embodiment;

FIGS. 5(a) to 5(e) illustrate the manufacture of an exemplary superconducting via at selected stages of a method according to a fourth embodiment;

FIGS. 6(a) and 6(b) schematically show an exemplary technique for measuring the resistance of a superconducting via;

FIGS. 7(a) to 7(g) are SEM images showing portions of a first type of exemplary semiconductor wafer in cross-section, and FIGS. 7(h) to 7(n) are SEM images showing portions of a second type of exemplary semiconductor wafer in cross-section, both after a via has been at least partially etched into the wafer;

FIGS. 8(a) to 8(c) are SEM images showing portions of the wall of a via at least partially formed in a semiconductor wafer after surface roughness reduction, while FIGS. 8(d) and 8(e) are images obtained by AFM topography on a top surface of the wafer after surface roughness reduction, at 5×5 μm area and 500×500 nm area respectively;

FIGS. 9(a) to 9(d) are SEM images showing portions of an exemplary semiconductor wafer of a first type in cross-section after a via has been at least partially etched into the wafer and a superconductor material deposited onto the wall of the via, FIGS. 9(e) to 9(h) are SEM images showing portions of another exemplary semiconductor wafer of the first type in cross-section after a via has been at least partially etched into the wafer, surface roughness reduction has been performed and a superconductor material deposited onto the wall of the via, and FIGS. 9(i) to 9(l) are SEM images showing portions of an exemplary semiconductor wafer of a second type in cross-section after a via has been at least partially etched into the wafer, surface roughness reduction has been performed and a superconductor material deposited onto the wall of the via;

FIG. 10 is a graph showing the conformality of the deposited film of superconductor material on the walls of the vias in FIGS. 9(a), 9(e) and 9(i) respectively, vs. distance to the top of the via, where conformality is defined as the ratio of the film thickness at the respective distance to the film thickness at the top of the via;

FIGS. 11(a) and 11(b) are plots showing resistance vs. temperature, measured from: (a) a 30 nm planar niobium nitride film on a silicon wafer; (b) a niobium nitride film coated on a silicon wafer having multiple vias in parallel, manufactured by a method in accordance with an embodiment of the invention;

FIGS. 12(a) and 12(b) shows examples of techniques for depositing superconductor material on the surfaces of a semiconductor wafer having a via manufactured by a method in accordance with embodiments of the invention;

FIGS. 13(a) and 13(b) are atomic force microscope images of part of the wall of a via etched in a method in accordance with an embodiment of the invention before and after smoothing;

FIGS. 14(a) to 14(c) are cross-sectional images of vias etched manufactured by a method in accordance with an embodiment of the second aspect of the invention, prior to deposition of superconductor material;

FIGS. 15(a) to 15(c) are cross-sectional images of vias etched manufactured by a method in accordance with an embodiment of the second aspect of the invention;

FIGS. 16(a) to 16(c) are cross-sectional images of vias etched manufactured by a method in accordance with an embodiment of the second aspect of the invention.

### DETAILED DESCRIPTION

The following embodiments will be described with reference to forming superconducting though-substrate-vias (“TSVs” or simply “vias”) in silicon wafers. However more generally the method is applicable to wafers of any superconductive material. Where a silicon wafer is utilised, the silicon may be intrinsic (undoped) silicon, n-doped or p-doped. Typical semiconductor wafers have a resistivity in the range 0.001 to 50,000 Ohm-cm. Generally the wafer may have a diameter in the range 50 to 300 mm and a preferred thickness in the range 100 to 8,000 μm (microns). Similarly, the embodiments will be illustrated using niobium nitride (NbN) as the superconductor material (which is preferred), but other superconducting materials (such as other metallic nitrides) may be used instead.

It should also be noted that, while the method is illustrated with references to wafers carrying no layers other than those mentioned, in practice the surface(s) of the wafer 1 can have pre-existing patterns (or other functional materials) in which case these patterns and/or materials will be protected by suitable masks during the manufacture of the TSV. For example, the wafer could be provided, before the via etched, carrying superconductor material deposited on the first and/or second surface in the region of the via(s) that will be formed by the method (preferably the same superconductor material, as that which will be deposited, but possibly a different one). The presence of superconductor material on the surface(s) of the wafer will allow the conductive pathway formed through manufactured via to extend onto the respective surface(s) of the semiconductor wafer. After treatment, the masks will be removed. The wafer 1 may also have a holding layer or another holding wafer at the backside, as will be exemplified below.

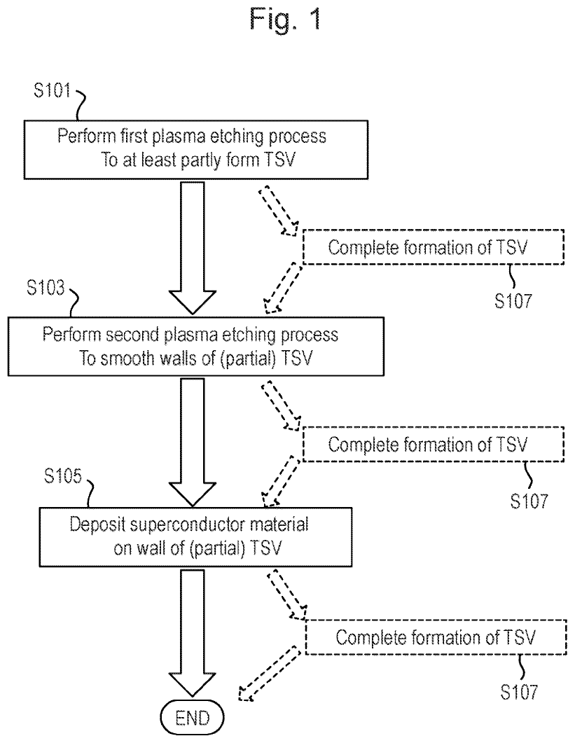

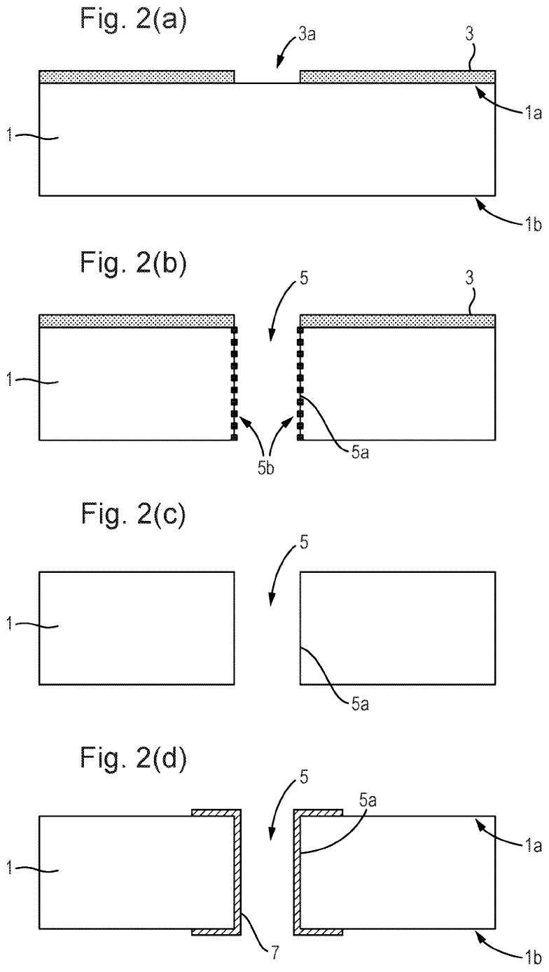

FIG. 1 is a flowchart illustrating steps of a method for manufacturing a superconducting TSV in accordance with embodiments of the invention. Step S107 (shown in dashed lines) is optional and, if performed, could be inserted at alternative points in the process as shown. The method will be described initially with reference to FIGS. 2(a) to 2(d) which illustrate an exemplary semiconductor wafer 1 and a via 5 being formed in it, at various stages during a first embodiment of the method. More details of preferred processes and process parameters suitable for performing each step will be given below.

In a first step S101, a first plasma etching process is used to at least partly form a TSV in semiconductor wafer (e.g. silicon wafer) 1. This typically involves first applying a patterned resist material 3 to a first surface 1a of the wafer, leaving a gap 3a corresponding to the lateral area of the desired TSV in which the wafer 1 is exposed, as shown in FIG. 2(a). The hole to be formed can take any lateral shape (e.g. round, square, slot), and any lateral width, preferred width dimensions being in the range 0.2 to 5,000 μm. The first plasma etching process (e.g. a Bosch process or cryo-etching) is then performed, causing removal of the semiconductor material from the first surface 1a of the wafer in the gap 3a and thus formation of a via 5 which initially extend at least part way through the thickness of the wafer 1. In the embodiment shown in FIG. 2, this step S101 is continued until the via 5 is fully formed (through the full thickness of the wafer), and as such step S107 can be omitted entirely. The resulting TSV 5 is shown in FIG. 2(b).

The first plasma etching process will typically cause the walls 5a of the via 5 to exhibit a degree of surface roughness (illustrated schematically at 5b), often referred to as “scalloping”. Preferably, the parameters of the first plasma etching process may be controlled to as to minimise the surface roughness as far as possible, as will be discussed below. Nonetheless in subsequent step S103, the wall 5a of the via 5 is smoothed (that is, its surface roughness is reduced) by performing a second plasma etching process. The second plasma etching process will be different from the first plasma etching process, at least in terms of its process parameters. For example, the second plasma etching process may be a reactive ion etching process. The resulting wafer 1 having a via 5 with smoothed sidewalls 5a is shown in FIG. 2(c). It will be noted that the remaining resist layer 3 has also been removed at this stage, which is optional and could be achieved by the second plasma etching process or separately.

Finally, in step S105, a superconductor material 7 such as a metallic nitride (preferably niobium nitride) is deposited onto at least part (preferably substantially all) of the wall 5a of the via 5, so as to form a superconductive pathway which electrically connects the first surface 1a to the second surface 1b of the wafer. The deposition of the superconductor material 7 in step S105 could be carried out from just one side of the wafer but more preferably takes place from both sides either sequentially or simultaneously. For example, in a preferred implementation step S105 may involve a first sub-step of depositing the semiconductor material 7 onto the wall 5a of the via 5 from the first side 1a of the wafer. Then, the wafer 1 may be turned over and a second sub-step of depositing the semiconductor material 7 onto the wall 5a of the via 5 from the second side 1b of the wafer may be performed.

It should be noted that the superconductor material 7 may additionally be deposited on one or both surfaces 1a, 1b of the wafer 1 and preferably this takes place during step S105 (simultaneously with coating of the material 7 onto the via wall 5a and/or before/after) so that the same tool and environment can be used. Preferably the semiconductor material deposited onto the surface(s) will be patterned as required by the application. This applies to all embodiments disclosed herein.

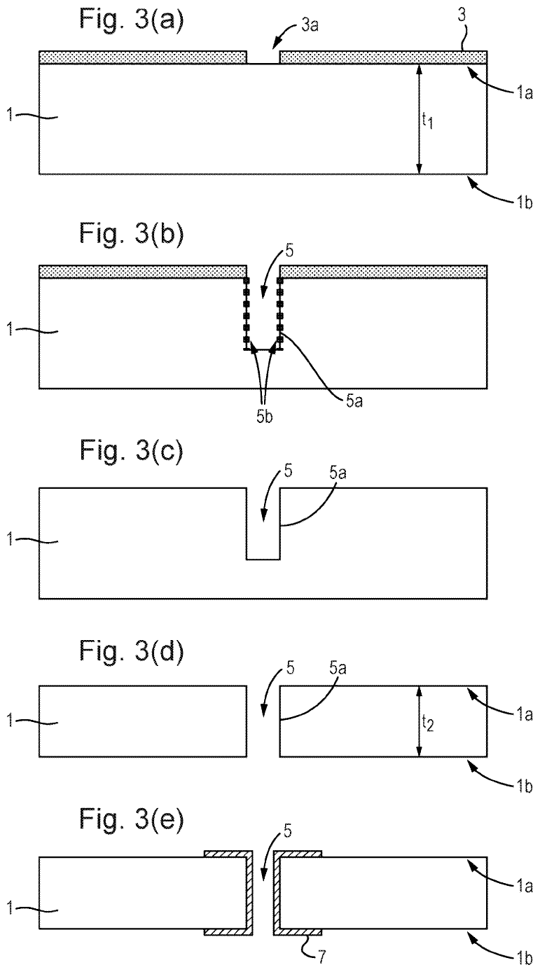

Another implementation of the method shown in the flowchart of FIG. 1 will be described with reference to FIG. 3, which depicts a second embodiment. As before, in a first step S101 a via 5 is etched into the first surface 1a of a semiconductor wafer 1 using a first plasma etching process and a patterned resist layer 3, as shown in FIG. 3(a). However, in this case the etch is halted before the via 5 is complete—that is, before the etch reaches the second surface 1b of the wafer 1, as shown in FIG. 3(b). This has the benefit that the wafer 1 is not perforated during the etching process, which ensures that any backside helium (or other gas) used to control wafer temperature does not leak to the front side of the wafer. Once again, the wall 5a of the resulting via 5 will have surface roughness 5b and in subsequent step S103 a second plasma etching process is performed to smooth the wall 5a. At this stage, the via 5 does not yet extend through the full thickness of the wafer 1. Next, in this example, in step S107 the via 5 is completed, i.e. made to extend through the full thickness of the wafer 5. Here, this is achieved by thinning the wafer 5 (either locally or across its whole area) which could be performed for instance by chemical-mechanical polishing (CMP) or wet etching of the second surface 1b, or plasma etching of the second surface 1b (e.g. by a plasma dry etch (F based) or a wet etch technique). That is, step S107 may involve reducing the thickness of the wafer 1 from its initial value t₁ to a smaller value t₂. Alternatively, in step S107, a targeted deep etch (corresponding to that of step S101) could be performed on the second surface 1b if this can be sufficiently accurately positioned so as to meet the existing portion of the via 5 inside the wafer 1. In this case it would be necessary to then smooth the wall of the extended via portion, e.g. by repeating step S103.

Finally, in step S105, a superconductor material 7 is deposited onto the smoothed wall 5a of the via 5 as previously described, to achieve an electrically conductive pathway between the first and second surfaces of the wafer 1.

It will be appreciated that, where the via 5 is only formed partially in step S101, its completion (step S107) could take place at various alternative points during the ensuing process. In the FIG. 2 embodiment, completion takes place after smoothing of the via wall 5a (step S103) and before deposition of the superconductor material 7 (step S105). However, the via 5 could alternatively be completed (by thinning of the wafer 1 or otherwise) in step S107 at any point in the process after step S101, for example: after step S101 but before step S103, or after step S105. It is also possible to divide any of steps S101, S103 or S105 into two or more sub-steps in which case the completion step S107 could happen between any of those sub-steps.

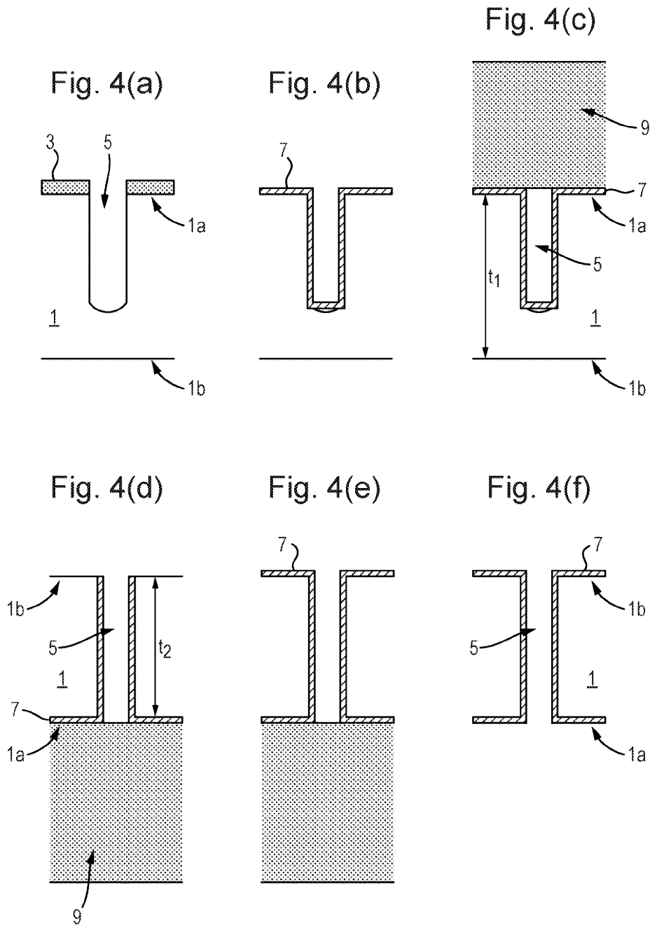

A third embodiment, in which step S105 is divided into two sub-steps, is illustrated in FIG. 4. Here, FIG. 4(a) shows the via 5 partially formed in the first surface 1a of wafer 1 following the first plasma etching process of step S101 and the second plasma etching process of step S102, resulting in smoothed sidewalls of the via 5. Next, the resist 3 is removed and then superconducting material 7 is deposited onto the wall of the via 5 from the first side 1a of the wafer as shown in FIG. 4(b), in a first sub-step of step S105. Then, a second wafer 9 is bonded onto the first surface 1a of the wafer 1 to provide structural support during the ensuing process steps, as shown in FIG. 4(c). It should be noted that contact between the two bonded wafers 1 and 9 may or may not be direct—for instance other layer(s), such as areas of the superconducting material 7, may be present between the wafers as shown. The construction is then turned over and the via 5 is completed in step S107 by thinning the wafer 1 from thickness t₁ to (smaller) thickness t₂ (preferably in a substantially uniform manner across the whole of the wafer area) such that the via 5 is revealed on the second surface 1b of the wafer (FIG. 4(d)). As noted in the previous embodiment, this may be achieved by CMP or a plasma etch, for example. Next, a second sub-step of step S105 is performed by depositing superconductor material 7 onto the wall 5a of the via 5 from the second surface 1b of the wafer 1, as shown in FIG. 4(e). Finally, the second wafer 9 is debonded, leaving the first wafer 1 with a though-substrate superconducting via 5 as shown in FIG. 4(f).

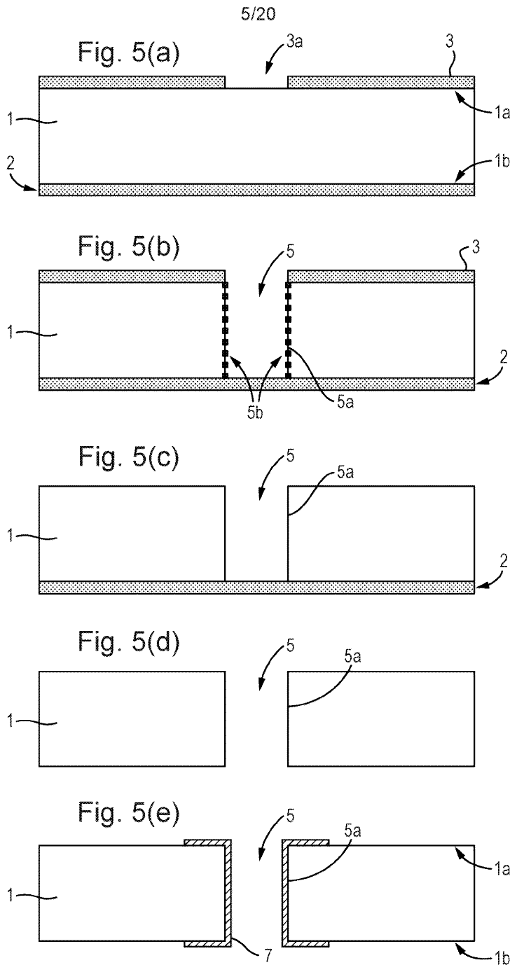

A fourth embodiment of the method is illustrated in FIG. 5. Here, prior to the start of the method, the wafer 1 is provided with a deposited (e.g. epitaxial) layer 2 deposited on its second surface 1b, as shown in FIG. 5(a). In the following examples, the deposited layer 2 is an epitaxial layer, but the layer could alternatively be deposited by a process other than epitaxial growth in other embodiments. For instance, the epitaxial layer 2 may comprise a dielectric such as silicon dioxide, or a superconducting material such as aluminium. The method starts, as before, by performing a first plasma etch process on the first surface 1a of the wafer 1, typically using a patterned resist material 3. A via 5 is formed and etching continues until the via 5 extends through (or nearly through) the full thickness of the wafer 1 and reaches the epitaxial layer 2, as shown in FIG. 5(b). The etch is halted before it proceeds through the full thickness of the epitaxial layer 2, in order to prevent leakage of backside helium (or other gas) used to maintain the temperature of the wafer 1 during processing. As before, the wall 5a of the resulting via 5 will have surface roughness 5b and in subsequent step S103 a second plasma etching process is performed to smooth the wall 5a, as shown in FIG. 5(c). If the epitaxial layer 2 is of a dielectric (or other non-superconductor) material, such as silicon dioxide, the epitaxial layer is then removed, for instance by all-over etching of the second surface 1b of the wafer 1 leaving both ends of the TSV 5 open as shown in FIG. 5(d). Finally, step S105 is performed to deposit superconducting material 7 onto the wall 5a of the via 5 and achieve an electrically conductive pathway between the first and second surfaces of the wafer 1. It will be appreciated that, if the epitaxial layer 2 itself comprises a superconducting material such as aluminium, it is not essential to remove the epitaxial layer 2 since this can form part of the electrically conductive pathway.

### Examples

In the following section, detailed examples of preferred processes and process parameters suitable for performing each of the above steps will be described. For brevity, the process steps will be described in the context of a version of the method according to the fourth embodiment above. However, it will be appreciated that the described processes can equally be applied to the corresponding steps of any of the embodiments disclosed herein. It should also be noted that, in order to demonstrate the benefits of the invention, the method is described below as applied to three wafers (substrates). The experimental methods disclosed below in connection with the two wafers of type A constitute comparative examples (since they do not result in full-thickness vias), whilst that disclosed in connection with the type B wafer constitutes a preferred embodiment of the present invention.

Positive photoresist 3 was patterned on two sets (A and B) of p-type high resistive (100) silicon substrates 1: (A) single-side polished wafers of 650=25 μm thickness; (B) dual-side polished wafers of 310±10 μm thickness. A layer 2 of 1 μm thickness silicon dioxide (SiO₂) was deposited on the backside of these wafers at 300° C. in a PECVD chamber, as shown in FIG. 5(a). This layer 2 ensured that the backside helium used to control wafer temperature did not leak to the front side of the wafer 1 once some of the vias 5 were etched through in step S101. This is necessary to ensure a high yield process that is robust to typical run—to run wafer thickness and etching rate non-uniformities (1% change in wafer thickness or etching rate equals 3 μm thickness or etching depth variation for a 300 μm thick wafer). Testing patterns consisted of holes with different diameters. The silicon exposed area was approximately 10% across a 150 mm wafer. The 13.5 μm thickness photoresist masks 3 were soft baked to keep a nearly vertical profile after lithography.

Process development focused on 60-80 μm diameter holes, targeting an aspect-ratio of 4-5:1. In step S101, deep silicon etching (DSiE) was performed on both sets of wafers in a specialised DRIE tool (such as the Oxford Instruments “Estrelas” tool). The source frequency was 2 MHz to generate a high density of fluorine radicals in the plasma. RF bias powers were applied from either 13.56 MHz high frequency (HF) or 350 kHz low frequency (LF) generators to the lower electrode with an electrostatic chuck (ESC) to generate a self-biasing voltage to vertically attract ions from the plasma to the wafer surface. After etching the TSVs 5 to a depth of around 320 μm, the remaining photoresist 3 was stripped, using oxygen plasma in an inductively couple plasma (ICP) chamber. A separate chamber for this step was utilised to avoid releasing fluorine residue from the DSiE chamber, which would increase TSV sidewall roughness. These wafers were subsequently etched in a RIE tool to remove sidewall scallops in FIG. 5(c). Backside silicon dioxide 2 on the set B wafers was also removed in the same RIE chamber, so that perforated TSV wafers were produced.

The TSV wafers were then transferred into a PEALD (plasma-enhanced atomic layer deposition) chamber (such as the Oxford Instruments “FlexAL”). Niobium nitride 7 was deposited into the TSVs at 250° C. using alternating TBTDEN ((tert-butylimido) bis(diethylamino) Niobium) vapour and mixed hydrogen/argon plasma steps with argon purge steps in between. An independent RF bias power (13.56 MHz) was applied on a lower electrode during deposition along with the plasma which was generated by a remote ICP source (13.56 MHz). Ion energy can influence film properties including stress, crystallinity, density, and resistivity. A film of 100 nm thick niobium nitride 7 was grown on two set A wafers and one set B wafer. Wafer A-1 did not receive plasma polishing (i.e. step S103 was omitted), while both wafer A-2 and B did receive the plasma polishing treatment (i.e. step S103 was performed). On wafer B, the 100 nm niobium nitride deposition was split into two separate 50 nm depositions-one deposition on each surface. The wafer B was transferred out from the PEALD chamber after the first 50 nm deposition, flipped, and immediately placed back into the PEALD chamber for the second 50 nm deposition.

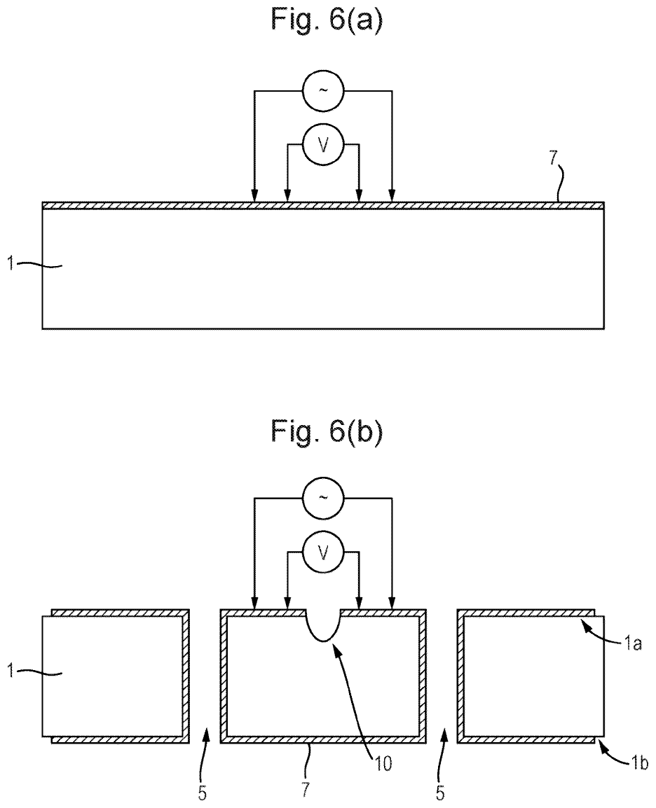

The superconductivity of the deposited niobium nitride film 7 was investigated on a non-patterned planar silicon wafer and the perforated TSV wafer B. The setup used four-point-probe resistance measurement in a closed cycle cooling system based on a Sumitomo RDK101D cold head and Sumitomo CNA-11C helium compressor unit, with precise temperature control from 2 K to 300 K and zero magnetic field, as shown in FIGS. 6(a) and 6(b). The perforated wafer B was diced to 15×15 mm size chips and measured in this setup to verify uninterrupted superconductivity of the niobium nitride through the full TSVs. A 0.5 mm wide isolation groove 10 throughout middle of the top surface was engraved into the silicon substrate 1 to ensure that the only possible conduction path over the groove was by way of TSV pairs it separated and through the backside coating, as shown in FIG. 6(b).

### Preferred Processes and Parameters for First Plasma Process (Step S101)

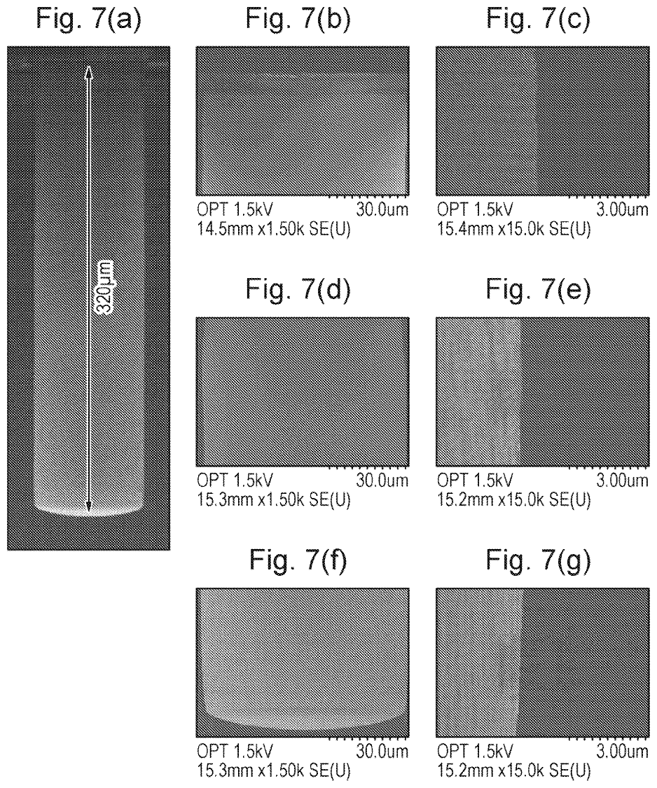

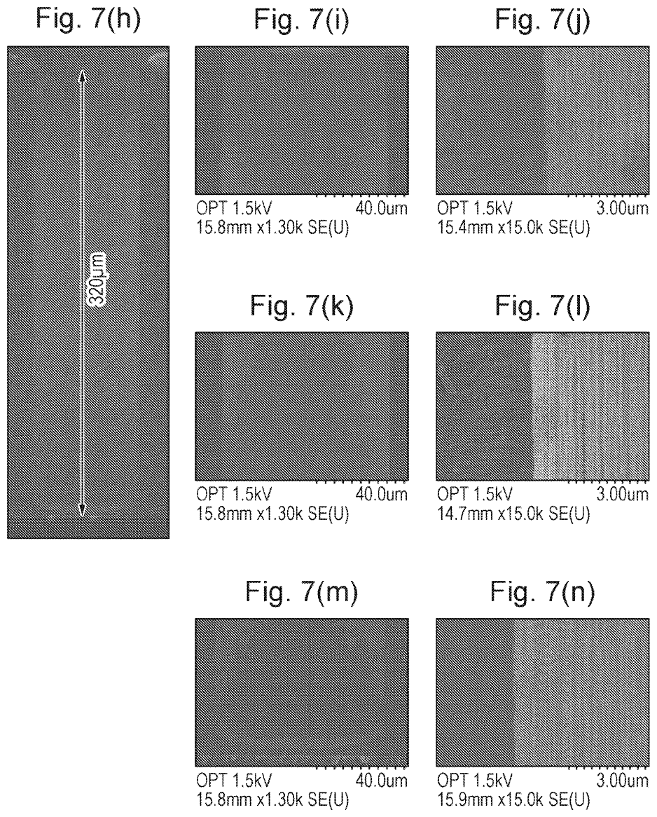

For highly anisotropic etching, a C₄F₈/SF₆ gas-chopping process (i.e., Bosch process) was preferred for this step, comprising alternating deposition, breakthrough and isotropic etch steps. Deep TSV etching is inherently challenging due to ion deflection by surface charging, which increasingly limit radical transport as feature depth increases and ions are increasingly lost to collisions. High source powers and high gas flows were employed in this process to achieve both sufficient etching rate and selectivity. The balance between deposition and breakthrough steps was key to ensure vertical sidewalls with minimal bow while also reducing striations on sidewalls. The scallops, which were produced by isotropic chemical etching of the silicon, were reduced in size by adjusting the duration of each etch step and using shorter cycle times (e.g. as disclosed in WO-A-2013/128181). Alternatively, by reducing plasma source power, gas flow, or process pressure, the number of radicals reaching the exposed silicon surface was also reduced and consequently the scallops. Nevertheless, both methods decreased etching rate and selectivity. Increasing bias power (ion energy) at multiple etch stages effectively cleared up fluorocarbon polymer residue at the bottom. The final process yielded 320 μm depth vias with 90-90.2° profile at wafer scale with a uniformity of <+1%, a selectivity of >50:1 and an etching rate of >6 μm/min, as shown in FIG. 7. Nevertheless, there were scallops (<80 nm) on the sidewalls, which could limit the quality and continuity of a superconducting film deposited by means of PVD, CVD or ALD. Although post-etch treatment by wet-etch can further smooth sidewalls, this step is not always feasible or desirable in all quantum device process flows due to potential material incompatibilities.

FIG. 7 shows SEM images of cross sections taken through the wafers after the above-described etching step. FIG. 7(a) shows a 320 μm depth, 75 μm diameter via formed in a silicon wafer of set A, and FIGS. 7(b) to 7(g) show details thereof, revealing sidewalls with scallops <80 nm at top, middle and bottom sections. FIG. 7(h) shows a 320 μm depth, 75 μm diameter via formed in a wafer of set B (note a few microns of silicon remain on top of the silicon oxide layer 2), and FIGS. 7(i) to 7(n) show details thereof, revealing sidewalls with scallops <80 nm at top, middle and bottom sections.

An alternative method to achieve relatively sidewalls is to etch silicon at cryogenic (Cryo) temperatures. To this end, the wafer was cooled to −120° C., and both SF₆ and O₂ gases were continuously fed to the plasma. Silicon oxyfluoride etch by-products are significantly less volatile at lower (e.g. cryo) temperatures, enabling it to act as a passivation layer. Ions continuously removed the passivation on the etch front and fluorine radicals then reacted with the exposed silicon. Profile evolution and sidewall smoothness were dominated by temperature, gas-ratio, and RF-bias power. Cryo etching did not achieve 300 μm depth in this work due to photoresist mask limitations, but a full TSV etch is possible with this technique using hard masks. The term “hard mask” refers to non-photoresist masks, and suitable materials for hard masks include Cr, Al, SiN, SiNO, Al₂O₃, or SiO₂, which may be patterned by etching through a resist mask.

### Preferred Processes and Parameters for Second Plasma Etch Process (Step S103)

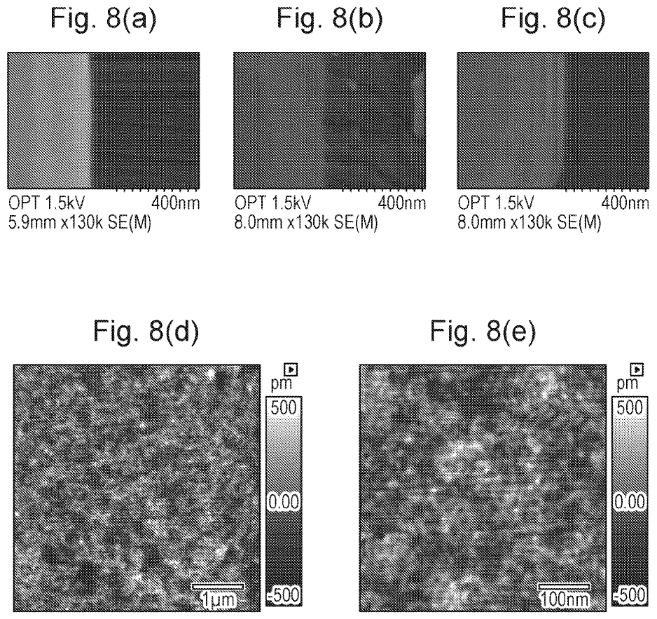

To achieve smoother sidewalls 5a, both wafer sets were treated by CF₄ based plasma with approximately 400 V DC bias at room temperature for 120 minutes, after removal of the photoresist mask and thin polymer residues on sidewalls. (Preferred process parameters: 10 mT/100W RF (400V bias)/100 sccm CF₄/20 degC, unclamped wafer without backside helium in a RIE chamber). This step successfully removed scallops as shown in FIG. 8(a) to (c), and the measured etching rate was 27 nm/min. As expected, both top and bottom were further etched at several microns' depth, but a notch did not appear on the silicon dioxide interface. Therefore, both depth and verticality of TSV 5 were maintained. FIGS. 8(a) to (c) are SEM images (x 130k) taken from top, middle and bottom sections of vias in the set B wafer, which show that the scallops have been removed from sidewalls 5.

The top surface of the set B wafer was characterized by an AFM tool (such as that available from Asylum) which revealed roughness of <300 μm (root-mean-square value, RMS) in FIGS. 8(d) and (e), which was like the pre-etch surface. FIGS. 8(d) and (e) show images obtained by AFM topography on post-etched silicon top surface at 5×5 μm area and 500×500 nm area respectively. Top surface roughness was important to maintain compatibility with further device fabrication processes on the surface afterwards. An alternative SF₆ chemistry was also investigated for this end, which supplied nine times higher silicon etching rate than the CF₄ chemistry because of higher fluorine radical density in plasma. Top surface roughness increased to over 2 nm (RMS) with the SF₆ chemistry. Therefore, the CF₄ chemistry was preferred.

While the above preferred process parameters were found in these experiments to give particularly good results, in more general terms this step may be performed using other plasma etching methods across a wide parameter range, appropriate values being selected so as to achieve good smoothing of the sidewalls:
1. 1-500 mT chamber pressure;
2. 5-1500V bias; 5-1500W RF power;
3. 10-1500 sccm gas flow of individual CF₄, SF₆, NF₃ or a mixture of any of these gases; and/or a mixture with Ar, O₂, H₂ or any other CFₓ gases;
4. Wide temperature range from −150~+150 degC; with clamp or unclamp methods; with or without backside helium;
5. Also with ICP, TCP source power (100-5000W) to increase etch rate;
6. To smooth the TSV sidewall, the process (step S103) can be implemented on one surface of the wafer or on both surfaces (after flip over of the wafer);

The backside silicon dioxide layer on the set B wafer was removed using the same CF₄ process. Selectivity between silicon and silicon dioxide was adjusted to nearly 1:1. This ensured post-etch surface flatness and smoothness for further processing on the surface or bonding with another wafer. These vias were further opened by over-etching into silicon. A notch was not observed even with a long over-etch step. Therefore, this process provides a wide process window, as is required for high yield quantum device fabrication.

### Preferred Processes and Parameters for Deposition (Step S105)

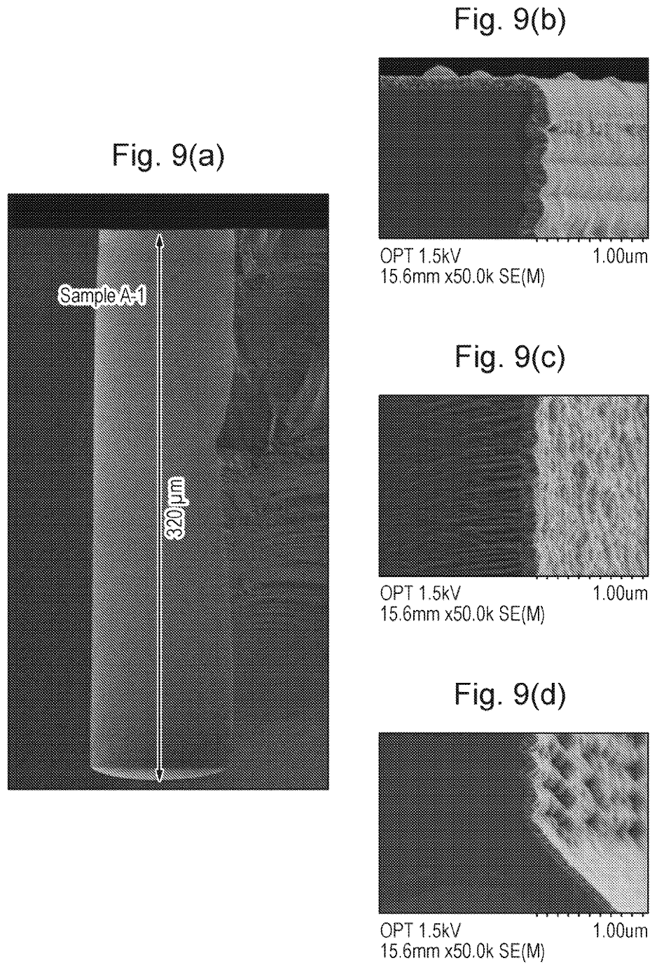

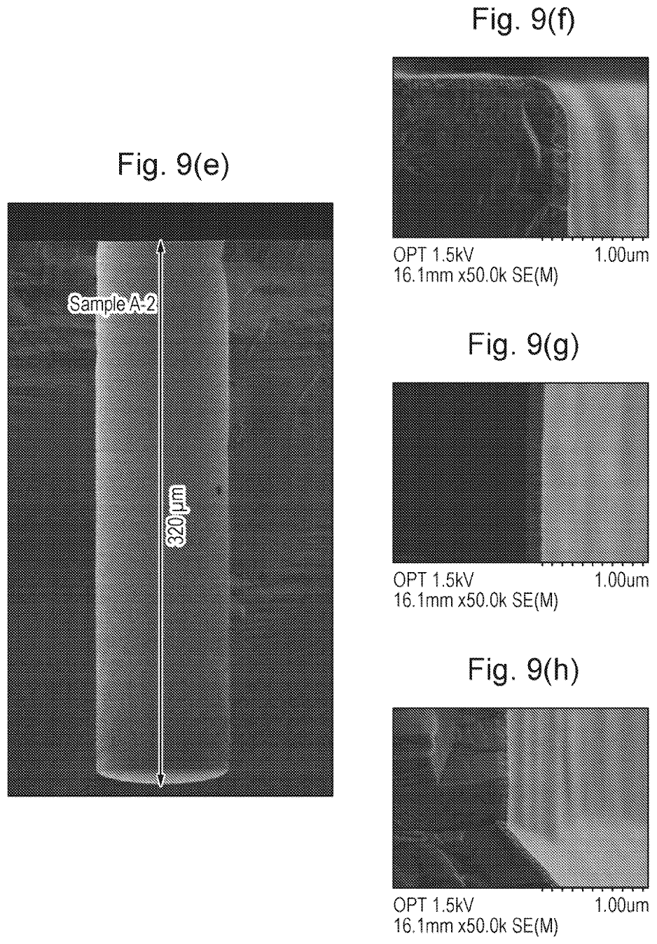

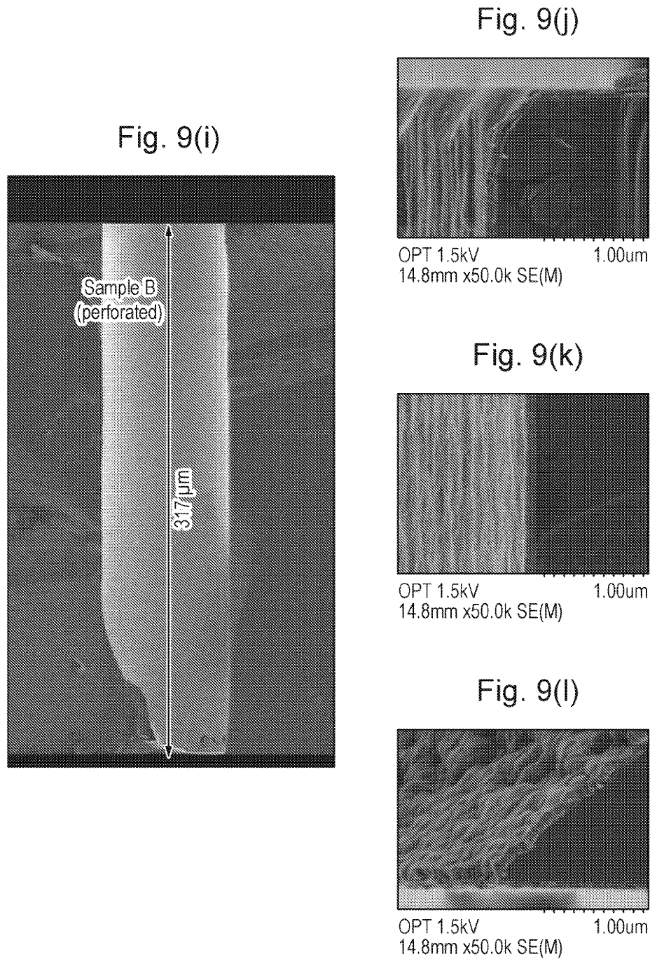

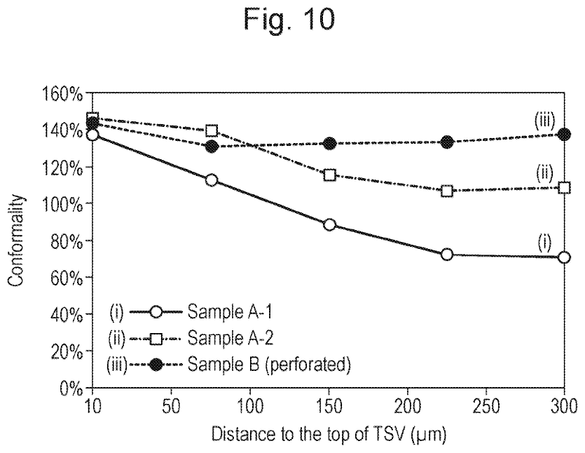

Next, 100 nm thick niobium nitride film (a superconductor material 7) was grown on the test wafers by PEALD with optimized biasing power. The thickness of the sidewall coating along the depth was investigated by SEM cross section images as shown in FIG. 9. Here, the images show cross-sections of TSVs at the centre of wafers A-1, A-2 and B. FIGS. 9(a)-(d) are SEM images showing cross-section of a TSV in sample A-(without plasma polish) at top, middle and bottom; FIGS. 9(e)-(h) are SEM images showing cross-section of a TSV in sample A-2 (with plasma polish) at top, middle and bottom; and FIGS. 9(i)-(l) are SEM images showing cross-section of a TSV in sample B at top, middle and bottom. Conformality was defined by a ratio of the film thickness on the sidewall at various depths into the via 5 over the film thickness at the top surface. Trends of different sample sets are compared in FIG. 10. It will be seen that the film thickness achieved in sample B is substantially uniform across the full depth of the via 5. The variation in film thickness was more pronounced in both of the A-type wafers, believed to be due to the deposition having been carried out from one side of the wafer only. Nonetheless it will be noted that the uniformity achieved is significantly improved in sample A-2 as compared with sample A-1, which demonstrates the effectiveness of the smoothing step (step S103). Super-conformality (i.e., >100%) was observed around TSV openings in FIG. 9 (b, f, j), where growth rate at the top was less than that at sidewalls due to different energy they received from directional ions. Enhanced lateral growth would reduce suppression of superconductivity in the TSVs. Nevertheless, the growth rate on sidewalls decreased towards the bottom of the TSV. On the sample A-1, there was >130% conformality around TSV openings, but approximately 70% conformality at bottom of sidewalls. These results suggested that growth saturation was limited by radicals' recombination or ions loss due to collisions on the sidewalls in the over 300 μm depth TSVs. A smooth topography would help to reduce such losses and decrease the variation of growth rate along the sidewalls. The sample A-2 which received sidewall polishing, had >100% conformality at all measured points. Furthermore, the sample B which received both sidewall polishing and dual-side deposition, had >130% conformality through the whole TSV because depositions from opposite directions made the coating inside TSVs more even.

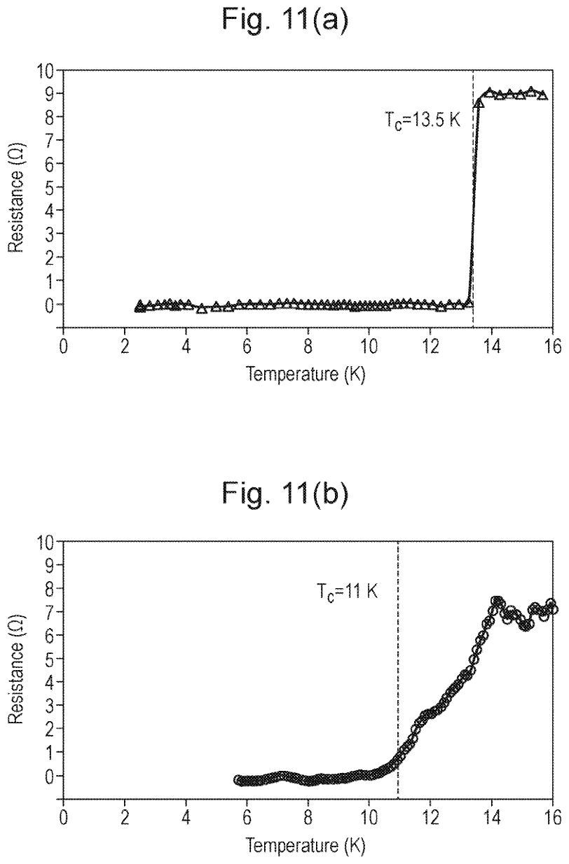

Superconductivity measured from a 30 nm niobium nitride planar sample (deposited on a silicon wafer) illustrated a sharp superconducting transition temperature (Tc) at 13.5 K, as shown in FIG. 11(a). This value was comparable to similar films which were deposited by ALD technique at higher temperatures (300-350° C.). FIG. 11(b) shows a broadened transition from 11 K to 14 K, which was measured from sample B as overall performance of multiple TSVs in parallel. Such transition profile suggests that the in-plane portion of the film may have been superconducting at approximately 14 K and the superconducting transition temperature gradually decreased through the depth of the TSV until all portions of the film were fully superconducting at approximately 11 K.

Superconducting TSVs are necessary for shielding, crosstalk reduction, and signalling in a range of superconducting quantum device applications. In this example superconductivity was achieved in a 5:1 aspect ratio TSV using DSiE, plasma polishing, and conformal PEALD niobium nitride. The plasma sidewall polishing process increased film conformality from 67% to 110%. The preferred combination of plasma polishing and PEALD technique achieved vertical superconducting TSVs at wafer scale. A record high superconducting transition temperature of 11 K was observed on the fabricated niobium nitride TSVs. Cryo TSV etching was also explored as a promising route to achieving smooth sidewalls for superconducting TSV applications. The superconducting TSV manufacturing process demonstrated here provides a reliable wafer-scale approach which uses commercially available fabrication tools and offers a high Tc, which allows the process to be used for a wide range of superconducting applications, including millikelvin temperature use cases such as qubit shielding and signalling, as well as SNSPD, quantum transduction, and other 4-10 K applications.

While preferred parameters for the PEALD step have been described above, it will be appreciated that this process could be performed across a larger range of parameters such as some or all of the following:
1. The superconductor material may be a metal nitride material including NbN, TiN, TaN, or a mixture of these materials.
2. The temperature of the wafer during the deposition may be controlled to a value in the range of 50 degrees Celsius (C) to 500° C.
3. The chamber pressure may be in the range of 20 mTorr to 1000 mTorr.
4. The process gas may include one or more of H₂, N₂, NH₃ and Ar flowed into the chamber at a rate in the range of 10-1000 sccm for each gas.
5. The power of the plasma source (e.g. an ICP, CCP or hollow cathode plasma source) may be in the range of 50 W to 2000 W.
6. The substrate table on which the wafer is arranged may be biased with an RF bias with power in the range of 0 W to 300 W and a DC offset voltage of magnitude in the range of 0 V to 300 V.
7. The period of time for which the wafer is exposed to plasma in each cycle of the ALD process may be in the range of 2 s to 300 s.

For example, the following combination of parameters may be used: the superconductor material may be deposited using TBTDEN purged between cycles using an H₂/Ar plasma at 250 C; ICP plasma source with a power of 300W and a 30 W RF bias applied to the substrate table with the plasma at a pressure of 10 mTorr with 80 sccm H₂ and 10 sccm Ar; 2 seconds TDTDEN dosing at 120 mTorr. The wafer could be ‘flipped’ after performing a portion of the intended number of ALD cycles.

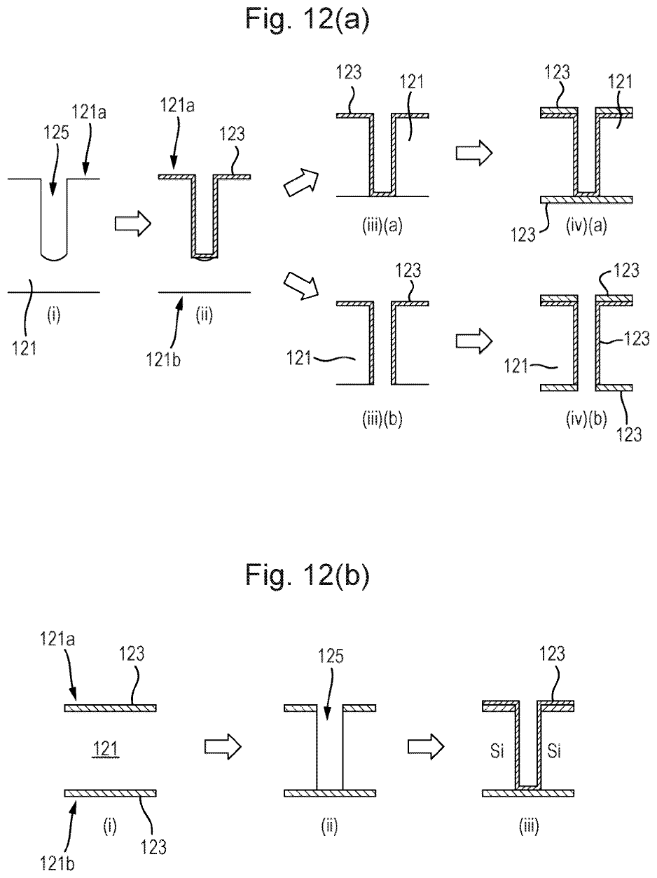

As mentioned previously, there may be superconductor material on the first and/or second surfaces of the wafer such that the conductive pathway through the via extends onto the first and/or second surface respectively. Examples of ways of forming this arrangement will now be described with reference to FIG. 12, the first of which is shown in FIG. 12(a). The semiconductor wafer 121 is initially etched, in a first step (i), from the first side to form partly a via 125 extending part-way through the wafer (like in the example of FIG. 4). Then, in step (ii), superconductor material 123 is deposited on the wall of the via and the first surface. As well as coating the wall of the via, the superconductor material is deposited on the base of the etched via. The wafer 121 is then thinned by etching the second surface 121b, in step (iii), to complete the via. This etching may be performed such that either (a) the superconductor material that was deposited on the base of the etched via remains in place, and thereby extends over the opening of the via on the second surface or (b) the superconductor material that was deposited on the base is removed, such that there is no material over the opening of the via on the second surface. Further superconductor material 123 is then deposited on the first and second surfaces in step (iv) to extend the conductive pathway of the via further across those surfaces.

FIG. 12(b) shows a second option for depositing superconductor material onto the first and second surfaces. Here, the wafer is provided at the outset with superconductor material 123 on the first surface and second surface. Then, the wafer is etched from the first side to form a via that extends through the wafer but leaving the superconductor material on the second surface at the location of the opening of the via in place. Then, superconductor material is deposited on the walls of the via while the first surface 121a is exposed to the source of the deposited material, with the result that further superconductor material 123 is deposited on the first surface overlapping that which was already present before the etching of the via. The deposited superconductor material here is also deposited onto the region of superconductor material that extends across the opening of the via 125 (inside the via) on the second surface 121b.

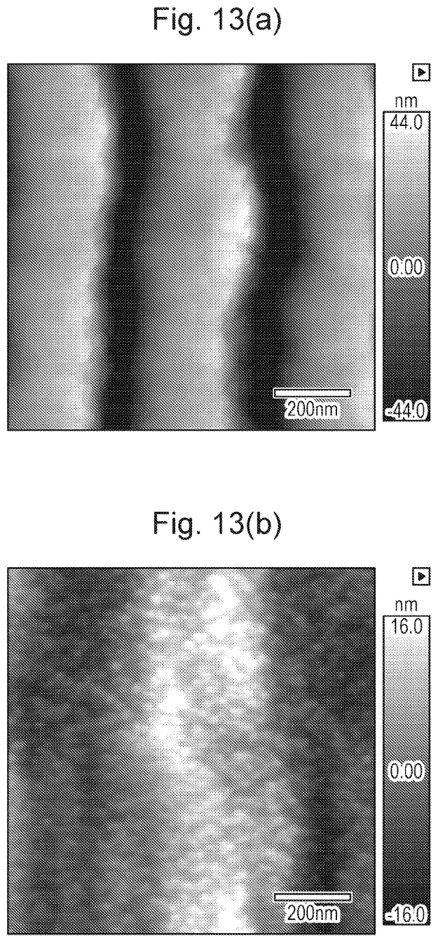

To illustrate further the advantages of smoothing the wall of the etched via in step (B) of the method, FIGS. 13(a) and (b) respectively show part of the wall of a via etched in a method in accordance with the first aspect of the invention before and after smoothing (or “plasma polishing”) in step (B). The greyscale tone of the image represents the depth of the surface relative to a notional plane (as indicated by the scales in the drawings). The via was etched (in step (A)) using a Bosch process, resulting in scallops having a depth of about 100 nm in the resulting via wall. After smoothing using a second plasma etching process, the variation in depth across the area shown was significantly less than that of the scallops, resulting in a smoother surface capable of promoting the formation of an ordered structure in the superconductor material deposited on it.

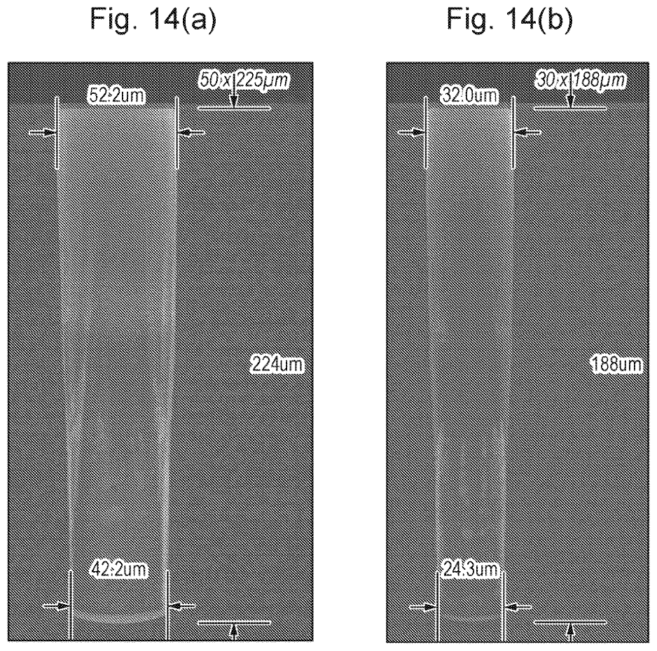

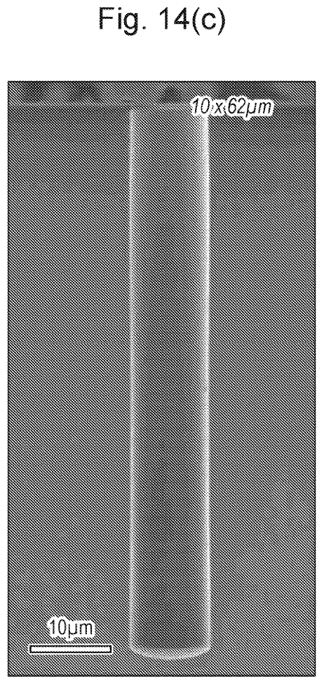

FIGS. 14(a)-(c) are images of vias that were etched using cryo etching in a method in accordance with an embodiment of the second aspect of the invention. These images show the vias prior to deposition of superconductor material on the via walls. The three vias shown were etched using the same cryo etching process but were etched to different depths (determined by the duration of time for which the etched wafer was exposed to the plasma) and with different lateral dimensions (determined by the hard masks that defined the lateral shapes of the three vias). In this cryo etching process, the plasma was generated from an etch gas mixture comprising oxygen (O₂) flowed at 10 sccm and sulphur hexafluoride (SF₆) flowed at 90 sccm. The pressure of the plasma was 10 mTorr. The temperature of the table on which the wafer was supported during the etching was controlled to a value of −100° C. and the table was biased with an RF bias signal having a power of 6 W. The plasma was generated from the etch gas mixture using an inductively coupled plasma source with a power of 600 W. It can be seen in each image that highly vertical sidewalls were formed, particularly in FIG. 14(c). As mentioned above, it is believed that the by-products of the etching—in this case silicon oxyfluoride—are much less volatile at cryogenic temperatures than at higher temperatures and thereby form a passivating layer on the walls of the via, which promotes vertical etching.

In general, the following parameter ranges are preferred for performing cryo etching in embodiments of methods in accordance with the second aspect of the invention (and the first aspect, where cryo etching is used as the first plasma etching process):
1. Plasma pressure in the range of 1 to 100 mTorr;
2. O₂ flow rate in the range of 1 to 50 sccm;
3. SF₆ flow rate in the range of 10-500 sccm;
4. Substrate temperature in the range of −150° C. to −50° C.;
5. RF bias power in the range of 3 to 100 W;
6. Plasma source (in particular ICP) power in the range of 100 to 2500 W.

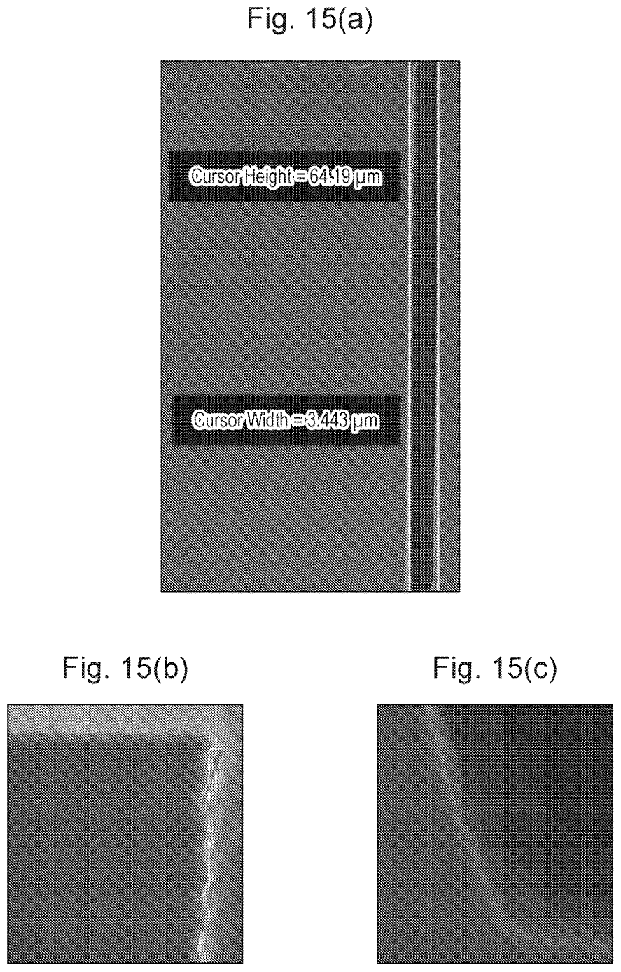

FIG. 15(a) is an image of a via manufactured by a method in accordance with an embodiment of the second aspect of the invention-though it should be noted that in this image, the via have not yet been completed as it does not yet extend onto the second surface of the wafer. The via was etched using a Bosch process and NbN was deposited on its wall using an atomic layer deposition process. FIGS. 15(b) and (c) are close-up views of parts of this via, which clearly show (in FIG. 15(b)) the ‘scalloped’ texture imparted to the wall of the via by the Bosch process. The Bosch process used here was controlled such that the roughness imparted by the via wall by the scallops was below 30 nm. The vertical white lines in FIG. 15(c) show the approximate bounds of the deposited NbN, the thickness of which is about 45.97 nm. The aspect ratio of the vias shown in FIGS. 15(a) to (c) (i.e. the ratio of their depth to lateral width) was about 20:1. FIG. 15(c) shows a section of the base of this via.

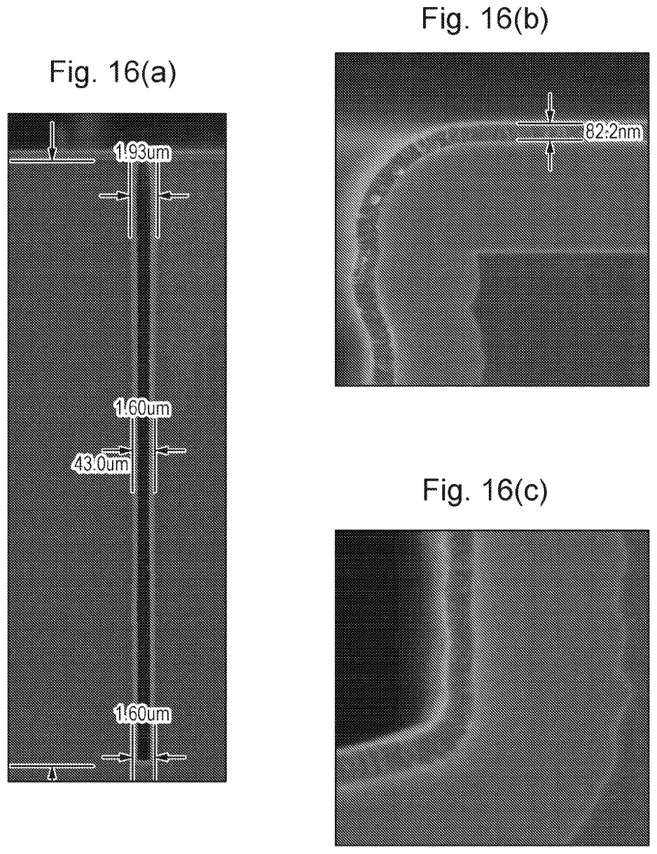

FIG. 16(a) is an image of another via manufactured by a method in accordance with an embodiment of the second aspect of the invention. Like in FIG. 15(a), in this image, the via has not yet been completed as it does not yet extend onto the second surface of the wafer. The via was etched using a Bosch process and TiN was deposited on its wall using an atomic layer deposition process. Again, the Bosch process was controlled such that the roughness of the wall of the via due to the scallops left by this process was less than 30 nm. FIGS. 16(b) and (c) are close-up views of this via. FIG. 16(b) shows the top of the via where it opens onto the first surface of the wafer. The TiN was deposited such that it extends onto the first surface of the wafer, as can be seen in this image. The thickness of the deposited layer varied between about 80 nm and 90 nm. FIG. 16(c) shows the base of the via (again, like FIG. 15(a), this via was not completed at the time of taking this image—in other words, the via was partly formed in step (A) and step (D) had not yet been performed). The aspect ratio of the vias shown in FIGS. 16(a) to (c) (i.e. the ratio of their depth to lateral width) was about 40:1. FIG. 16(c) is a detailed view of the base of this via.

1. A method of manufacturing a superconducting via through a semiconductor wafer having opposed first and second surfaces, the method comprising:
(A) forming, at least partly, a via extending through the semiconductor wafer from the first surface to the second surface by etching into the first surface of the semiconductor wafer using a first plasma etching process; and then:
(B) using a second plasma etching process different from the first plasma etching process, etching the wall of the via so as to reduce its surface roughness;
(C) after step (B), depositing a superconductor material on at least a portion of the wall of the via; and
(D) if the via was not formed completely in step (A), completing the formation of the via such that the via extends from the first surface to the second surface of the semiconductor wafer;
whereby the deposited superconductor material forms an electrically conductive pathway electrically connecting the first and second surfaces of the semiconductor wafer.

2. The method of claim 1, further comprising:
before step (A), providing the semiconductor wafer, the semiconductor wafer having a deposited layer on the second surface thereof, and wherein the deposited layer is present on the second surface of the semiconductor wafer during step (A), preferably also in step (B); and
after step (A), if the deposited layer is not a superconducting deposited layer, removing the deposited layer from the second surface of the semiconductor wafer;
the method preferably further comprising applying a cooling gas, preferably helium, to the deposited layer during the etching in step (A), preferably also in step (B).

3. (canceled)

4. The method of claim 2, wherein the deposited layer is formed of silicon dioxide (SiO₂).

5. The method of claim 1, wherein the via is formed partly in step (A), and wherein completing the formation of the via in step (D) comprises removing material from the second surface of the semiconductor wafer;
wherein preferably the removal of material in step (D) is substantially uniform across the second surface of the semiconductor wafer, thereby thinning the wafer.

6. (canceled)

7. The method of claim 5, wherein the removal of material in step (D) is performed by plasma etching.

8. The method of claim 5, further comprising, after partly forming the via in step (A) and before completing the formation of the via in step (D), bonding a support substrate onto the first surface of the semiconductor wafer;
wherein preferably step (D) is performed while the semiconductor wafer is bonded to the support substrate;
the method preferably further comprising separating the support substrate from the semiconductor wafer after step (D).

9. (canceled)

10. The method of claim 1, wherein the superconductor material is deposited in step (C) by an atomic layer deposition process, preferably plasma-enhanced atomic layer deposition.

11. The method of claim 1, further comprising depositing the superconductor material on the first surface and/or the second surface of the wafer such that the electrically conductive pathway extends from the via onto the first surface and/or the second surface.

12. The method of claim 1, wherein the etching in step (A) is performed through a patterned mask arranged on the first surface of the wafer and defining the lateral shape of the via;
the method preferably further comprising, after step (A), removing the patterned mask.

13. The method of claim 1, wherein the resulting superconducting via has a superconducting transition temperature greater than 10 Kelvin.

14. (canceled)

15. The method of claim 1, wherein the superconductor material is a metallic nitride, preferably niobium nitride (NbN).

16. (canceled)

17. The method of claim 1, wherein the etched via has a smallest lateral dimension in the range of 0.2 μm to 5000 μm, preferably 60-80 μm.

18. The method of claim 1, wherein the ratio of the thickness of the semiconductor wafer to the smallest lateral dimension of the etched via is in the range of 1:1 to 70:1, preferably in the range of 3:1 to 20:1, more preferably in the range of 4:1 to 10:1.

19. The method of claim 1, wherein:
the first plasma etching process is a Bosch process or a cryo etching process; and/or
the second plasma etching process is a reactive ion etching process.

20. (canceled)

21. The method of claim 1, wherein the second plasma etching process comprises etching the wall of the semiconductor wafer using a plasma generated from a gas mixture that comprises:
at least one fluorine-bearing gas, more preferably at least one of CF₄, SF₆ and NF₃; and/or
at least one of Ar, O₂ and H₂.

22. The method of claim 1, wherein the second plasma etching process is performed at a pressure in the range of 1 mTorr to 500 mTorr, preferably about 10 mTorr.

23. The method of claim 1, wherein in step (B), the semiconductor wafer is arranged on a substrate table while the second plasma etching process is being performed;
wherein preferably an RF bias is applied to the substrate table during the second plasma etching process, and preferably the RF bias has a value in the range of 5 V to 1500 V, preferably about 400 V, and/or the power of the applied RF bias is in the range of 5 W to 1500W, preferably about 100 W.

24. (canceled)

25. The method of claim 1, wherein in the second plasma etching process, the plasma used to etch the wall of the semiconductor wafer is generated using an inductively-coupled plasma source, preferably at a power in the range of 100 W to 5000 W.

26. The method of claim 1, wherein the deposition of the superconductor material in step (C) is performed by atomic layer deposition, preferably plasma-enhanced atomic layer deposition.

27. A method of manufacturing a superconducting via through a semiconductor wafer having opposed first and second surfaces, the method comprising:
(A) forming, at least partly, a via extending through the semiconductor wafer from the first surface to the second surface by etching into the first surface of the semiconductor wafer using a plasma etching process such that the wall of the etched via has a surface roughness of less than 30 nanometres (nm); and then:
(C) depositing a superconductor material on at least a portion of the wall of the via; and
(D) if the via was not formed completely in step (A), completing the formation of the via such that the via extends from the first surface to the second surface of the semiconductor wafer;
whereby the deposited superconductor material forms an electrically conductive pathway electrically connecting the first and second surfaces of the semiconductor wafer.
